(19) United States
(12) Patent Application Publication
(10) Pub. No.: US 2024/0297078 A1
(43) Pub. Date: Sep. 5, 2024

(54) METHOD OF MANUFACTURING SEMICONDUCTOR DEVICE, AND METHOD OF SEPARATING SUBSTRATE

(71) Applicant: Kioxia Corporation, Tokyo (JP)

(72) Inventors: Mariko SUMIYA, Yokkaichi Mie (JP); Takuro OKUBO, Yokkaichi Mie (JP)

(73) Assignee: Kioxia Corporation, Tokyo (JP)

(21) Appl. No.: 18/586,425

(22) Filed: Feb. 24, 2024

(30) Foreign Application Priority Data
Mar. 2, 2023 (JP) 2023-031991

(51) Int. Cl. H01L 21/78; H01L 21/02; H01L 21/3205; H01L 21/321; H01L 21/3213; H01L 21/683; H01L 21/762; H01L 23/00; H10B 80/00

(52) U.S. Cl. CPC H01L 21/7813; H01L 21/02381; H01L 21/02532; H01L 21/02614; H01L 21/32055; H01L 21/3212; H01L 21/32134; H01L 21/6835; H01L 21/76259; H10B 80/00; H01L 24/80; H01L 2221/68386; H01L 2224/80006; H01L 2924/1431

(57) ABSTRACT

In one embodiment, a method of manufacturing a semiconductor device includes forming a first insulator or a first conductor layer on a first substrate, forming a porous layer on the first insulator or the first conductor layer, forming a first film including a first device, above the porous layer, and forming a second film including a second device, on a second substrate. The method further includes bonding the first substrate and the second substrate to sandwich the first insulator or the first conductor layer, the porous layer, the first film, and the second film. The method further includes separating the first substrate and the second substrate such that the first insulator or the first conductor layer and a first portion of the porous layer remain above the first substrate, and a second portion of the porous layer remains above the second substrate.

### CROSS REFERENCE TO RELATED APPLICATION

This application is based upon and claims the benefit of priority from the prior Japanese Patent Application No. 2023-031991, filed on Mar. 2, 2023, the entire contents of which are incorporated herein by reference.

### FIELD

Embodiments described herein relate to a method of manufacturing a semiconductor device, and a method of separating a substrate.

### BACKGROUND

When a substrate and another substrate are bonded to manufacture a semiconductor device, these substrates are occasionally separated after the bonding. In this case, a method capable of suitably separating these substrates is desirably employed.

### BRIEF DESCRIPTION OF THE DRAWINGS

FIGS. 1 to 3 are sectional views showing a structure of a semiconductor manufacturing apparatus of a first embodiment;

FIGS. 4A to 7C are sectional views showing a method of manufacturing a semiconductor device of the first embodiment;

FIGS. 8A to 9C are sectional views showing a method of manufacturing a semiconductor device of a comparative example of the first embodiment;

FIG. 10 is a sectional view showing the structure of a semiconductor device of the first embodiment;

FIG. 11 is a sectional view showing a structure of a columnar portion of the first embodiment;

FIG. 12 is a sectional view showing the method of manufacturing the semiconductor device of the first embodiment;

FIGS. 13A to 16C are sectional views showing a method of manufacturing a semiconductor device of a second embodiment;

FIG. 17 is a sectional view showing details of the method of manufacturing the semiconductor device of the second embodiment; and

FIGS. 18A and 18B are sectional views showing details of the method of manufacturing the semiconductor device of the second embodiment.

### DETAILED DESCRIPTION

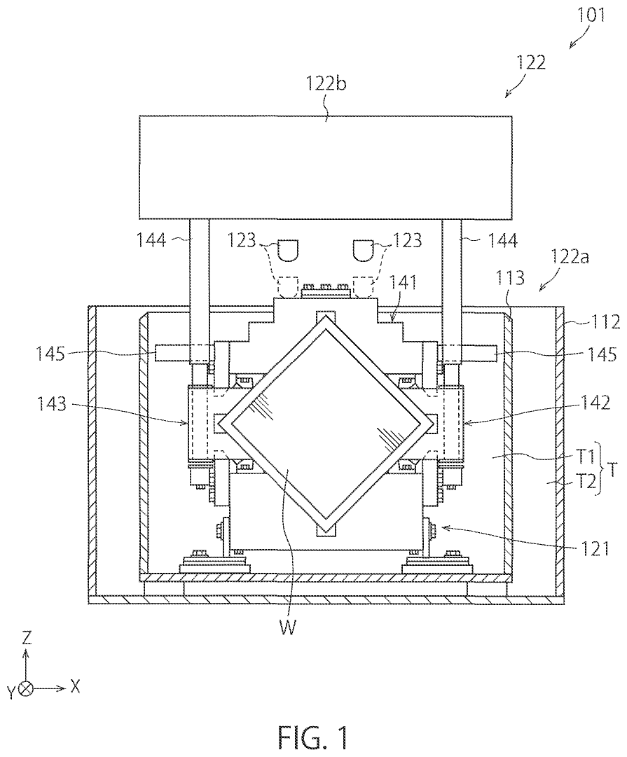

Embodiments will now be explained with reference to the accompanying drawings. In FIGS. 1 to 18B, the same configurations are given the same signs and their duplicate description is omitted.

In one embodiment, a method of manufacturing a semiconductor device includes forming a first insulator or a first conductor layer on a first substrate, forming a porous layer on the first insulator or the first conductor layer, forming a first film including a first device, above the porous layer, and forming a second film including a second device, on a second substrate. The method further includes bonding the first substrate and the second substrate to sandwich the first insulator or the first conductor layer, the porous layer, the first film, and the second film. The method further includes separating the first substrate and the second substrate such that the first insulator or the first conductor layer and a first portion of the porous layer remain above the first substrate, and a second portion of the porous layer remains above the second substrate.

### First Embodiment

FIGS. 1 to 3 are sectional views showing a structure of a semiconductor manufacturing apparatus 101 of a first embodiment.

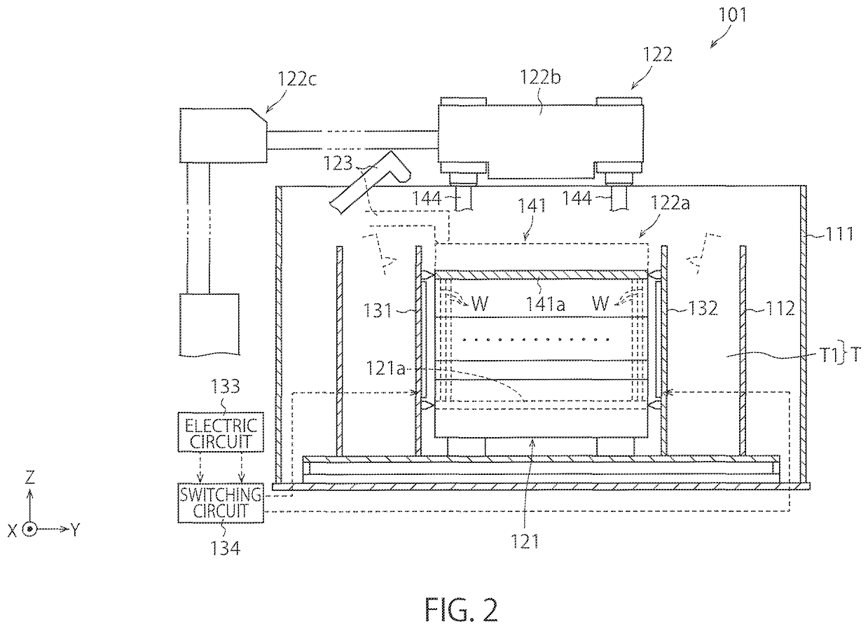

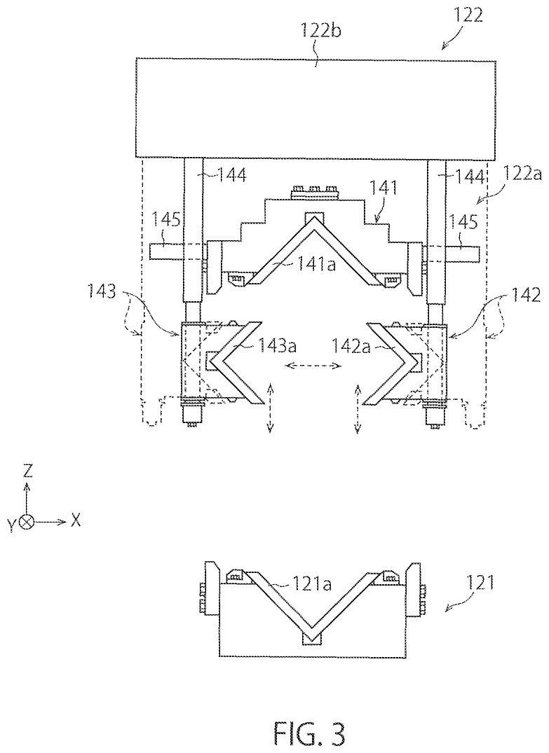

An example of the semiconductor manufacturing apparatus 101 is an anodization apparatus that forms a porous layer on a surface of a substrate by an anodization method. FIGS. 1 and 2 show different elevational sections of the semiconductor manufacturing apparatus 101. FIG. 3 shows a part of the semiconductor manufacturing apparatus 101 in detail.

FIGS. 1 to 3 show an X-direction, a Y-direction, and a Z-direction perpendicular to one another. In this specification, the +Z-direction is taken as the upward direction and the −Z-direction is taken as the downward direction. Furthermore, a direction parallel to the Z-direction is taken as the up-down direction and a direction perpendicular to the Z-direction is takes as a horizontal direction. The −Z-direction may coincide with the direction of gravity or do not have to coincide with the direction of gravity.

The semiconductor manufacturing apparatus 101 includes an outer container 111, an inner container 112, a partition 113, a lower holder 121, a transporting robot 122, a plurality of pressing arms 123, an electrode 131, an electrode 132, an electric circuit 133, and a switching circuit 134. The transporting robot 122 includes an upper holder 122a, a suspending unit 122b, and a movement mechanism 122c, and the upper holder 122a includes an upside holder 141, a left-side holder 142, a right-side holder 143, a plurality of suspending arms 144, and a locking bar 145. The lower holder 121, the upside holder 141, the left-side holder 142, and the right-side holder 143 include elastic members 121a, 141a, 142a, and 143a, respectively.

As shown in FIGS. 1 and 2, the inner container 112 is arranged in the outer container 111, and the partition 113 is arranged in the inner container 112. Consequently, the inner container 112 forms a reservoir tank T including an inner tank T1 inside the partition 113 and an outer tank T2 between the partition 113 and the inner container 112. The reservoir tank T stores an electrolyte solution. The electrolyte solution is fed to the inner tank T1 from a not-shown weighing tank, and the electrolyte solution that overflows from the inner tank T1 via an upper portion on the partition 113 is recovered by the outer tank T2. The inner tank T1 can contain a plurality of substrates W. An example of a planar shape of these substrates W is a circle or a quadrangle. The planar shape of the substrate W exemplarily shown in FIG. 1 is a quadrangle.

The lower holder 121 is arranged in the inner tank T1. The lower holder 121 together with the upper holder 122a of the transporting robot 122 holds the plurality of substrates W in the inner tank T1. As shown in FIG. 3, the upper holder 122a includes the upside holder 141, the left-side holder 142, and the right-side holder 143. Each substrate W is pinched and held by the lower holder 121, the upside holder 141, the left-side holder 142, and the right-side holder 143. Each substrate W is held by the lower holder 121, the upside holder 141, the left-side holder 142, and the right-side holder 143 in such a manner as to be in contact with the elastic members 121a, 141a, 142a, and 143a.

The transporting robot 122 includes the upper holder 122a, the suspending unit 122b that suspends the upper holder 122a, and the movement mechanism 122c that moves the suspending unit 122b. The transporting robot 122 can move the upper holder 122a in the up-down direction and the horizontal direction with the suspending unit 122b and the movement mechanism 122c. The suspending unit 122b can move the upside holder 141, the left-side holder 142, and the right-side holder 143 using the suspending arms 144 and the locking bar 145.

The pressing arms 123 press the upside holder 141 downward. Thereby, the lower holder 121 is pressed by the upside holder 141 via the left-side holder 142 and the right-side holder 143.

The electrodes 131 and 132 are arranged in the inner tank T1 and used for electrically processing the substrates W held by the lower holder 121 and the upper holder 122a. The electrodes 131 and 132 can simultaneously process the plurality of substrates W held by the lower holder 121 and the upper holder 122a (batch processing). For example, when the electrode 131 is a positive electrode and the electrode 132 is a negative electrode, a porous layer can be formed on the surface of each substrate W on the electrode 132 side.

The electric circuit 133 applies voltage to the electrode 131 and the electrode 132. For example, the electric circuit 133 includes a direct current (DC) power supply that applies DC voltage to the electrode 131 and the electrode 132.

The switching circuit 134 is arranged between the electric circuit 133 and the electrodes 131 and 132. For example, the switching circuit 134 can switch a polarity of DC voltage applied from the electric circuit 133 in predetermined cycles.

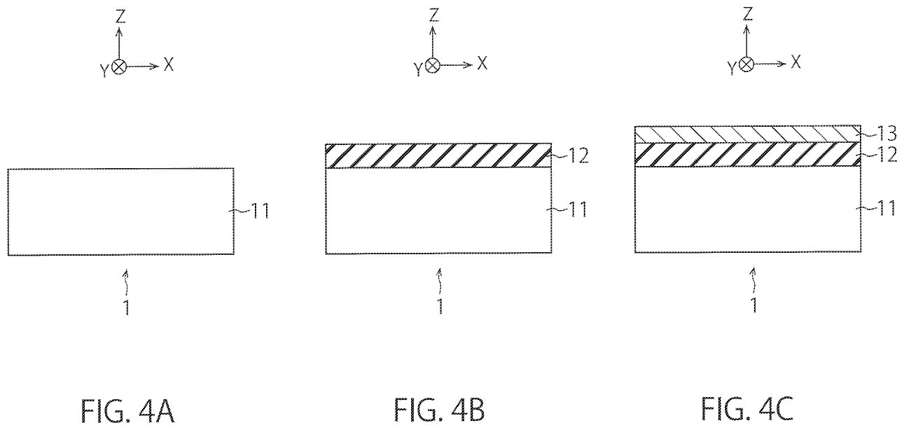

FIGS. 4A to 7C are sectional views showing a method of manufacturing a semiconductor device of the first embodiment. In the present embodiment, a semiconductor device is manufactured by bonding a wafer 1 and a wafer 2 mentioned later.

First, a substrate 11 for the wafer 1 is prepared (FIG. 4A). An example of the substrate 11 is a semiconductor substrate such as a silicon substrate. An example of a resistivity of the substrate 11 is 20 to 30 Ω·cm. The substrate 11 is an example of a first substrate.

Next, an insulator 12 is formed on the substrate 11 (FIG. 4B). An example of the insulator 12 is a SiO₂ film (silicon oxide film), a SiN film (silicon nitride film), or a SiCN film (silicon carbonitride film). An example of a thickness of the insulator 12 is 20 nm or less, preferably 5 to 10 nm. The insulator 12 is an example of a first insulator.

Next, a porous layer 13 is formed on the insulator 12 (FIG. 4C). An example of the porous layer 13 is a porous semiconductor layer such as a porous polysilicon layer. For example, the porous layer 13 is formed by forming a material layer for forming the porous layer 13 on the insulator 12, and then, forming pores in the material layer. Namely, the porous layer 13 is formed by making the material layer porous, i.e., by porosifying the material layer. When the material layer is a polysilicon layer (semiconductor layer), the porous layer 13 is the porous polysilicon layer (porous semiconductor layer). For example, the material layer is made porous by putting the substrate 11, which has the insulator 12 and the material layer formed, in the aforementioned semiconductor manufacturing apparatus 101, and then, applying the anodization method to the material layer. Thereby, the material layer changes into the porous layer 13 by the anodization method.

When the porous layer 13 is the porous semiconductor layer, the porous layer 13 may include p-type impurity atoms or n-type impurity atoms. Examples of the impurity atom in the porous layer 13 are a B (boron) atom, a P (phosphorus) atom, an As (arsenic) atom, an In (indium) atom, and a Ga (gallium) atom. In this case, an example of a concentration of the p-type impurity atoms or the n-type impurity atoms in the porous layer 13 is 2.5×10²⁰ atoms/cm³ or more. For example, the porous layer 13 can include the impurity atoms by the aforementioned material layer including the impurity atoms. In general, as the material layer has a lower resistivity, the material layer is more readily made porous by the anodization method. The present embodiment makes it possible, by setting the concentration of the impurity atoms in the material layer to be high, to make the resistivity of the material layer low and to make the material layer readily porous by the anodization method.

An example of the resistivity of the porous layer 13 is equal to or less than a two-thousandth of the resistivity of the substrate 11. Specifically, an example of the resistivity of the porous layer 13 is about 0.01 Ω·cm. Such a low resistivity can be attained, for example, by adjusting the concentration of the impurity atoms in the porous layer 13. An example of a thickness of the porous layer 13 is 100 to 20000 nm. An example of a porosity of the porous layer 13 is 40% or more, preferably 50% or more. An example of the porosity of the porous layer 13 means a ratio of pores per unit area on the porous layer 13. The porosity of the porous layer 13 can be measured, for example, by spectral ellipsometry or a gas absorption method. An example of gas used for the gas absorption method is Kr (krypton) gas or N₂ (nitrogen) gas.

When the anodization method is performed, charges move in the substrate 11, the insulator 12, and the aforementioned material layer. Therefore, a thickness of the insulator 12 is desirably made small such that the insulator 12 does not disturb movement of the charges. Therefore, the thickness of the insulator 12 is set to be 20 nm or less, for example, and preferably set to be 5 to 10 nm.

Moreover, the anodization method of the present embodiment is performed, for example, under the following conditions. An example of a current density is 132 mA/cm². An example of the electrolyte solution used is liquid including HF (hydrogen fluoride) and H₂O (water) in 1:3.8. The electrolyte solution may be liquid including HF, H₂O, and C₂H₅OH (ethanol). An example of a processing time is 20 seconds. The present embodiment makes it possible, by making the aforementioned material layer, not the substrate 11, porous, to perform formation of pores by the anodization method readily even in the case of using the substrate 11 that has a high resistivity.

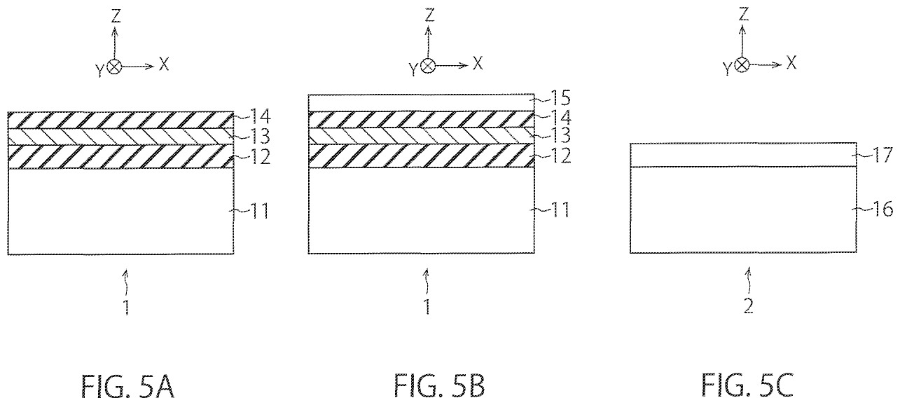

Next, a diffusion preventing layer 14 is formed on the porous layer 13 (FIG. 5A). The diffusion preventing layer 14 is formed for preventing impurity atoms from diffusing from the porous layer 13 to a layer afterward formed on the diffusion preventing layer 14. An example of the diffusion preventing layer 14 is a SiO₂ film, a SiN film, or an AlOx film (aluminum oxide film). An example of a thickness of the diffusion preventing layer 14 is 10 to 100 nm.

Next, a device layer 15 is formed on the diffusion preventing layer 14 (FIG. 5B). The device layer 15 is a layer including device(s) as constituent(s) of the semiconductor device of the present embodiment. As such a device, for example, the device layer 15 includes a memory cell array of a three-dimensional memory. The device layer 15 is an example of a first film, the aforementioned device(s) each being an example of a first device.

Next, a substrate 16 for the wafer 2 is prepared and a device layer 17 is formed on the substrate 16 (FIG. 5C). An example of the substrate 16 is a semiconductor substrate such as a silicon substrate. The substrate 16 is an example of a second substrate. The device layer 17 is a layer including device(s) as constituent(s) of the semiconductor device of the present embodiment. As such a device, for example, the device layer 17 includes a circuit that controls operation of the aforementioned memory cell array. The device layer 17 is an example of a second film, the aforementioned device(s) each being an example of a second device.

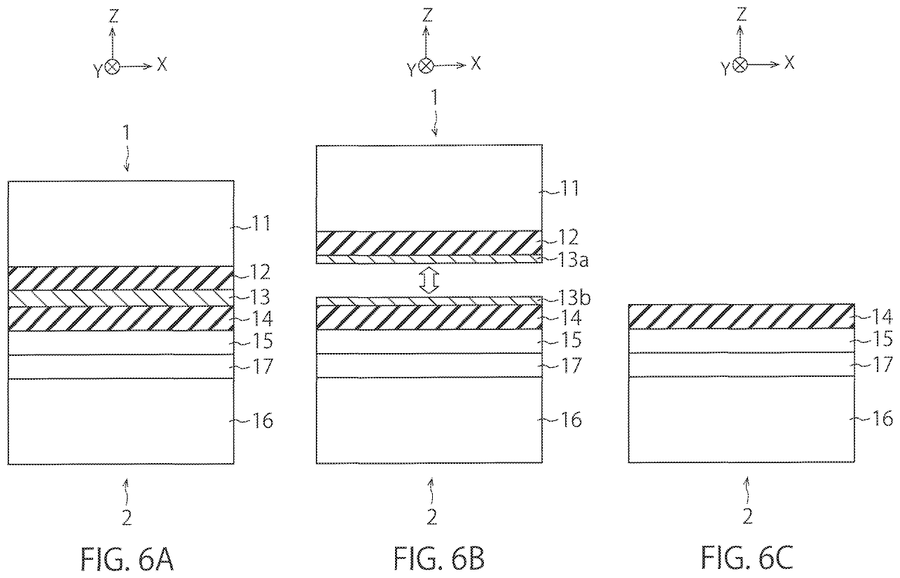

Next, the wafer 1 and the wafer 2 are bonded (FIG. 6A). Specifically, the substrate 11 and the substrate 16 are bonded so as to sandwich the insulator 12, the porous layer 13, the diffusion preventing layer 14, the device layer 15, and the device layer 17. Thereby, the substrate 11 and the substrate 16 are bonded such that the device layer 15 and the device layer 17 are in contact with each other. The device layer 15 and the device layer 17 may face each other via another layer instead of being in contact with each other. In FIG. 6A, an up-down orientation of the wafer 1 is reversed, and the wafer 1 is bonded on the wafer 2.

FIG. 6A shows a stacked structure including the wafer 1 and the wafer 2. This stacked structure is divided into a plurality of chips in an afterward dicing step. An example of each chip is a three-dimensional memory. Each of the stacked structure and the chips after dicing is an example of a semiconductor device.

Next, the wafer 1 and the wafer 2 bonded are separated (FIG. 6B). Note that the wafer 1 and the wafer 2 of the present embodiment are separated with a plane in the porous layer 13 being as a boundary, not at an interface between the device layer 15 and the device layer 17. FIG. 6B shows a porous layer 13a that is a portion of the porous layer 13 and a porous layer 13b that is the remaining portion of the porous layer 13. The wafer 1 and the wafer 2 of the present embodiment are separated such that the porous layer 13 is divided into the porous layer 13a and the porous layer 13b. The porous layer 13a is an example of a first portion, and the porous layer 13b is an example of a second portion.

In the present embodiment, the substrate 11 and the substrate 16 bonded in the step of FIG. 6A are separated in the step of FIG. 6B. In this stage, the porous layer 13 is divided into the porous layer 13a and the porous layer 13b as mentioned above. Consequently, the insulator 12 and the porous layer 13a remain on the substrate 11, and the device layer 17, the device layer 15, the diffusion preventing layer 14, and the porous layer 13b remain on the substrate 16.

In other words, in the step of FIG. 6B, the substrate 11 together with the insulator 12 and the porous layer 13a is peeled off from the substrate 16. This peeling-off plane in this stage is the plane in the porous layer 13, that is, the plane between the porous layer 13a and the porous layer 13b.

The porous layer 13 has a lower physical hardness than the material layer before being made porous. Therefore, the present embodiment makes it possible to separate the wafer 1 and the wafer 2 readily with the plane in the porous layer 13 being as the boundary in the step of FIG. 6B. This plane may be positioned at any place in the porous layer 13.

Next, the porous layer 13b is removed from the wafer 2 (FIG. 6C). After that, the wafer 2 is divided into a plurality of chips by a dicing step. An example of each chip of the present embodiment is a three-dimensional memory including the aforementioned memory cell array in the device layer 15 and the aforementioned circuit in the device layer 17.

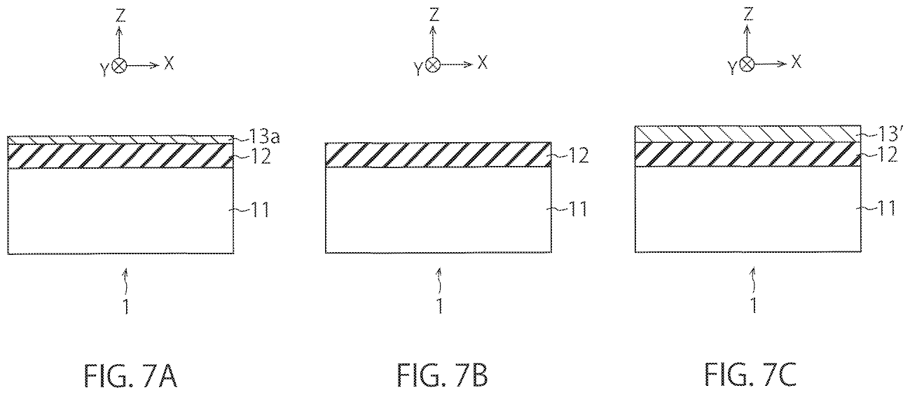

FIG. 7A shows the wafer 1 separated from the wafer 2. In the method of the present embodiment, next, the porous layer 13a is removed from the wafer 1 (FIG. 7B). The porous layer 13a is removed, for example, by wet etching. An example of a liquid chemical used in this wet etching is a mixed aqueous solution including HF (hydrofluoric acid), HNO₃ (nitric acid), and CH₃COOH (acetic acid). The porous layer 13a may be removed by CMP (Chemical Mechanical Polishing) instead of the wet etching.

When the porous layer 13a is removed by the wet etching, the insulator 12 is used as an etching stopper against the wet etching. This makes it possible to remove the porous layer 13a such that the substrate 11 is not made thin by the wet etching. In general, when the porous layer 13a is a semiconductor layer, an etching selectivity between the porous layer 13a and the insulator 12 is high. Moreover, in general, when the substrate 11 is a semiconductor substrate and the porous layer 13a is a semiconductor layer, an etching selectivity between the substrate 11 and the porous layer 13a is low. Namely, the etching selectivity between the substrate 11 and the insulator 12 is higher than the etching selectivity between the substrate 11 and the porous layer 13a. Therefore, the present embodiment makes it possible, by using the insulator 12 as an etching stopper, to perform wet etching suitably. Likewise, when the porous layer 13a is removed by CMP, the insulator 12 is used as a polishing stopper against the CMP.

Next, a porous layer 13′ similar to the porous layer 13 is formed on the insulator 12 that remains on the substrate 11 (FIG. 7C). After that, the steps of FIGS. 4C to 7B are reperformed using the wafer 1 that includes the porous layer 13′. This makes it possible to reuse the substrate 11 for the wafer 1 for manufacturing a semiconductor device. For example, by repeatedly performing the method of the present embodiment using one substrate 11 and N substrates 16, a plurality of chips (three-dimensional memories) can be manufactured from each of the N substrates 16 (N is an integer of two or more).

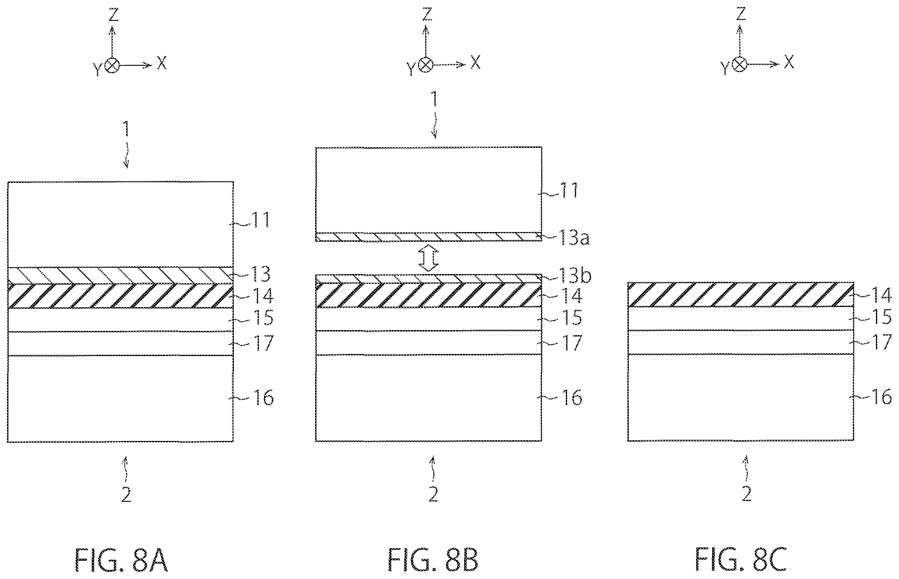

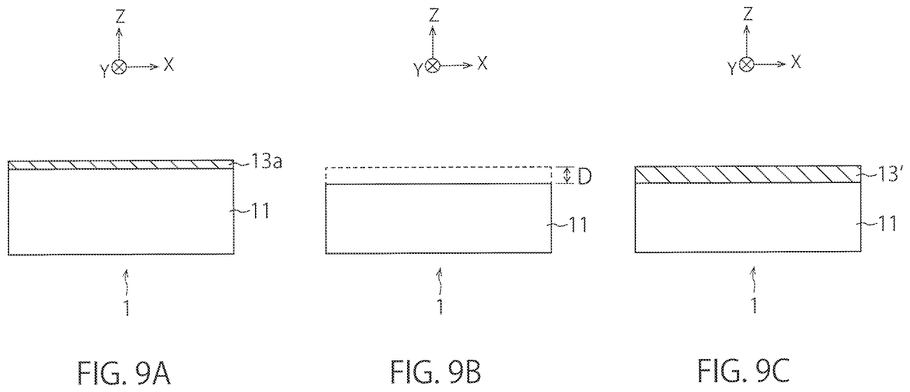

FIGS. 8A to 9C are sectional views showing a method of manufacturing a semiconductor device of a comparative example of the first embodiment.

FIG. 8A is a sectional view corresponding to FIG. 6A. In FIG. 8A, the wafer 1 and the wafer 2 are bonded. Note that the wafer 1 of this comparative example does not include the insulator 12.

Next, the wafer 1 and the wafer 2 are separated (FIG. 8B). The wafer 1 and the wafer 2 of this comparative example are also separated with a plane in the porous layer 13 being as the boundary. Therefore, the porous layer 13 is divided into the porous layer 13a and the porous layer 13b. Consequently, the porous layer 13a remains on the substrate 11, and the device layer 17, the device layer 15, the diffusion preventing layer 14, and the porous layer 13b remain on the substrate 16.

Next, the porous layer 13b is removed from the wafer 2 (FIG. 8C). After that, the wafer 2 is divided into a plurality of chips by a dicing step.

FIG. 9A shows the wafer 1 separated from the wafer 2. In the method of this comparative example, next, the porous layer 13a is removed from the wafer 1 (FIG. 9B). The porous layer 13a is removed, for example, by wet etching (or CMP).

In this comparative example, for example, when the substrate 11 is a semiconductor substrate and the porous layer 13 is a semiconductor layer, the etching selectivity between the substrate 11 and the porous layer 13a is low. Consequently, there is a possibility that the substrate 11 is made thin by wet etching. Moreover, since the surface of the substrate 11 is exposed by the wet etching, there is a possibility of some harmful influence on the surface of the substrate 11, such as damage thereon due to the wet etching. FIG. 9B shows a situation that the thickness of the substrate 11 decreases by a thickness “D” due to the substrate 11 being made thin. Such a phenomenon can also occur when the porous layer 13a is removed by CMP.

Next, the porous layer 13′ similar to the porous layer 13 is formed on the substrate 11 (FIG. 9C). After that, the steps of FIGS. 8A to 9B are reperformed using the wafer 1 that includes the porous layer 13′. In this case, when the surface of the substrate 11 is damaged or the substrate 11 is made thin due to the wet etching or the CMP, there is a concern that reuse of the substrate 11 is disturbed. On the other hand, in the present embodiment, the porous layer 13a is provided on the substrate 11 via the insulator 12. This makes it possible to restrain the surface of the substrate 11 from being damaged and/or the substrate 11 from being made thin due to wet etching or CMP. This therefore makes it possible to remove the porous layer 13a from the substrate 11 such that the substrate 11 is readily reused.

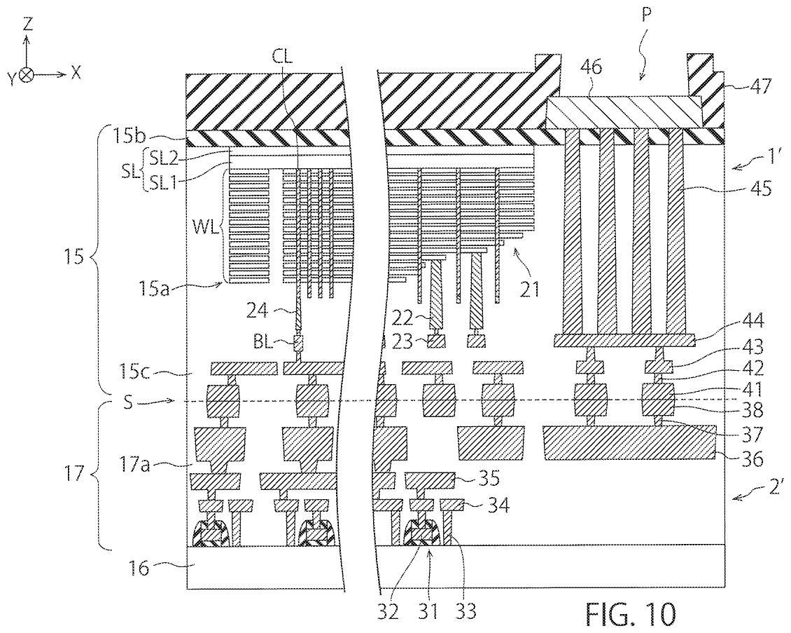

Hereafter, with reference to FIGS. 10 to 12, an example of the semiconductor device of the first embodiment is described.

FIG. 10 is a sectional view showing the structure of the semiconductor device of the first embodiment. The semiconductor device in FIG. 10 is a three-dimensional memory having an array region 1′ originated from the wafer 1 and a circuit region 2′ originated from the wafer 2 bonded.

The array region 1′ includes the device layer 15. The device layer 15 in FIG. 10 includes a memory cell array 15a including a plurality of memory cells, an insulator 15b on the memory cell array 15a, and an inter layer dielectric 15c beneath the memory cell array 15a. An example of the insulator 15b is a SiO₂ film or a SiN film. An example of the inter layer dielectric 15c is a stacked film including a SiO₂ film and another insulator.

The circuit region 2′ is provided beneath the array region 1′. Sign S denotes the plane (surface) where the array region 1′ and the circuit region 2′ are bonded. The circuit region 2′ includes the device layer 17 and the substrate 16 beneath the device layer 17. The device layer 17 in FIG. 10 includes an inter layer dielectric 17a between the inter layer dielectric 15c and the substrate 16. An example of the inter layer dielectric 17a is a stacked film including a SiO₂ film and another insulator.

The array region 1′ includes, as a plurality of electrode layers in the memory cell array 15a, a plurality of word lines WL and a source line SL. FIG. 10 shows a step structure portion 21 of the memory cell array 15a. The word lines WL are electrically connected to a word interconnect layer 23 via contact plugs 22. Columnar portions CL, penetrating the plurality of word lines WL, are electrically connected to bit lines BL via via plugs 24 and electrically connected to the source line SL. The source line SL includes a first layer SL1 as a semiconductor layer and a second layer SL2 as a metal layer.

The circuit region 2′ includes a plurality of transistors 31. Each transistor 31 includes a gate electrode 32 provided on the substrate 16 via a gate insulator, and not-shown source diffusion layer and drain diffusion layer provided in the substrate 16. Moreover, the circuit region 2′ includes a plurality of contact plugs 33, an interconnect layer 34, and an interconnect layer 35. Each of the plurality of contact plugs 33 is provided on the gate electrode 32, the source diffusion layer, or the drain diffusion layer of each of the plurality of transistors 31. The interconnect layer 34 is provided on the plurality of contact plugs 33 and includes a plurality of interconnects. The interconnect layer 35 is provided on the interconnect layer 34 and includes a plurality of interconnects.

The circuit region 2′ further includes an interconnect layer 36 provided on the interconnect layer 35 and including a plurality of interconnects, a plurality of via plugs 37 provided on the interconnect layer 36, and a plurality of metal pads 38 provided on these via plugs 37. For example, the metal pads 38 include a Cu (copper) layer or an Al (aluminum) layer. The circuit region 2′ functions as a control circuit (logic circuit) that controls operation of the array region 1′. The control circuit is constituted of the transistors 31 and the like and electrically connected to the metal pads 38.

The array region 1′ includes a plurality of metal pads 41 provided on the metal pads 38 and a plurality of via plugs 42 provided on the metal pads 41. Moreover, the array region 1′ includes an interconnect layer 43 provided on these via plugs 42 and including a plurality of interconnects and an interconnect layer 44 provided on the interconnect layer 43 and including a plurality of interconnects. For example, the metal pads 41 include a Cu layer or an Al layer. The aforementioned bit lines BL are included in the interconnect layer 44. Moreover, the aforementioned control circuit is electrically connected to the memory cell array 15a via the metal pads 41, 38, and the like and controls operation of the memory cell array 15a via the metal pads 41, 38, and the like.

The array region 1′ further includes a plurality of via plugs 45 provided on the interconnect layer 44, a metal pad 46 provided on these via plugs 45 and on the insulator 15b, and a passivation film 47 provided on the metal pad 46 and on the insulator 15b. The metal pad 46 includes a Cu layer or an Al layer, for example, and functions as an externally connecting pad (bonding pad) of the semiconductor device in FIG. 10. An example of the passivation film 47 is a stacked film including a SiO₂ film and another insulator and has an opening P from which an upper face of the metal pad 46 is exposed. The metal pad 46 can be connected via this opening P with bonding wires, solder balls, metal bumps, and the like to a mount board or another device.

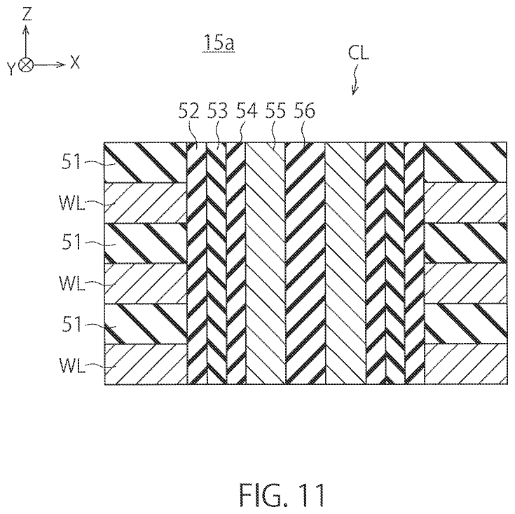

FIG. 11 is a sectional view showing a structure of the columnar portion CL of the first embodiment.

As shown in FIG. 11, the memory cell array 15a includes the plurality of word lines WL and a plurality of insulators 51 alternately stacked above the inter layer dielectric 15c (FIG. 10). An example of the word lines WL is a W (tungsten) layer. An example of the insulators 51 is a SiO₂ film.

The columnar portion CL sequentially includes a block insulator 52, a charge storage capacitor 53, a tunnel insulator 54, a channel semiconductor layer 55, and a core insulator 56. An example of the charge storage capacitor 53 is a SiN film and is formed on lateral faces of the word lines WL and the insulators 51 via the block insulator 52. The charge storage capacitor 53 may be a semiconductor layer such as a polysilicon layer. An example of the channel semiconductor layer 55 is a polysilicon layer and is formed on a lateral face of the charge storage capacitor 53 via the tunnel insulator 54. An example of the block insulator 52, the tunnel insulator 54, and the core insulator 56 is a SiO₂ film.

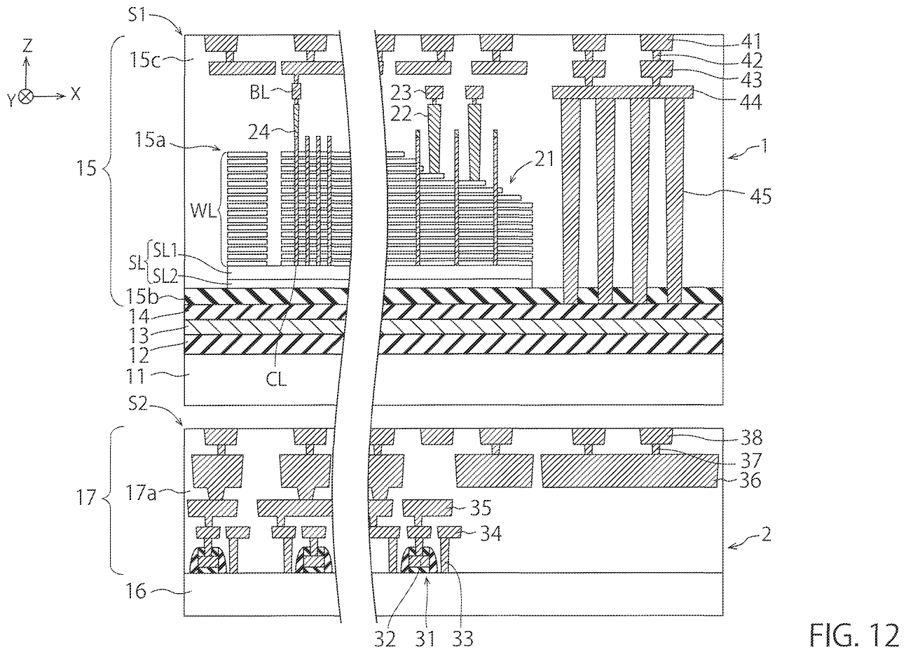

FIG. 12 is a sectional view showing the method of manufacturing the semiconductor device of the first embodiment.

FIG. 12 shows the wafer 1 including a plurality of the array regions 1′ and the wafer 2 including a plurality of the circuit regions 2′. The orientation of the wafer 1 in FIG. 12 is reverse to the orientation of the array region 1′ in FIG. 10. In the present embodiment, the wafer 1 and the wafer 2 are bonded thereby to afford the semiconductor device. FIG. 12 shows the wafer 1 before being reversed for the bonding, and FIG. 10 shows the array region 1′ after being reversed for the bonding and then being diced.

In FIG. 12, sign S1 denotes an upper face of the wafer 1, and sign S2 denotes an upper face of the wafer 2. The wafer 1 includes, beneath the insulator 15b, the substrate 11 provided via the diffusion preventing layer 14, the porous layer 13, and the insulator 12.

As shown in FIG. 12, in the present embodiment, first, the insulator 12, the porous layer 13, the diffusion preventing layer 14, the insulator 15b, the memory cell array 15a, the inter layer dielectric 15c, the metal pad 41, and the like are formed on the substrate 11 of the wafer 1. For example, above the substrate 11, the via plugs 45, the interconnect layer 44, the interconnect layer 43, the via plugs 42, and the metal pads 41 are sequentially formed. Moreover, the inter layer dielectric 17a, the transistors 31, the metal pads 38, and the like are formed on the substrate 16 of the wafer 2. For example, above the substrate 16, the contact plugs 33, the interconnect layer 34, the interconnect layer 35, the interconnect layer 36, the via plugs 37, and the metal pads 38 are sequentially formed.

Next, the wafer 1 and the wafer 2 are bonded as shown in FIG. 10 with mechanical pressure. Thereby, the inter layer dielectric 15c and the inter layer dielectric 17a are bonded together. Next, the wafer 1 and the wafer 2 are annealed at 400° C. Thereby, the metal pads 41 and the metal pads 38 are joined together.

After that, the substrate 11 and the substrate 16 are separated with the plane in the porous layer 13 being as the boundary, and the substrate 16 and the various layers on the substrate 16 are cut into a plurality of chips. As above, the semiconductor device in FIG. 10 is manufactured. The metal pad 46 and the passivation film 47 are formed on the insulator 15b, for example, after the substrate 11 and the substrate 16 are separated and the porous layer 13b and the diffusion preventing layer 14 on the substrate 16 are removed.

As above, in the present embodiment, the porous layer 13 is formed on the substrate 11 via the insulator 12, and the substrate 11 and the substrate 16 are bonded. Further, after the substrate 11 and the substrate 16 are bonded, the substrate 11 and the substrate 16 are separated. Therefore, the present embodiment makes it possible to separate these substrates 11 and 16 suitably after the bonding. For example, this makes it possible to separate the substrate 11 and the substrate 16 readily with the plane in the porous layer 13 being as the boundary and to remove the porous layer 13a from the substrate 11 in a mode suitable for reusing the substrate 11. Moreover, using the insulator 12 as a stopper in removing the porous layer 13a from the substrate 11 makes it possible to make the selectivity between the porous layer 13a and the stopper high.

### Second Embodiment

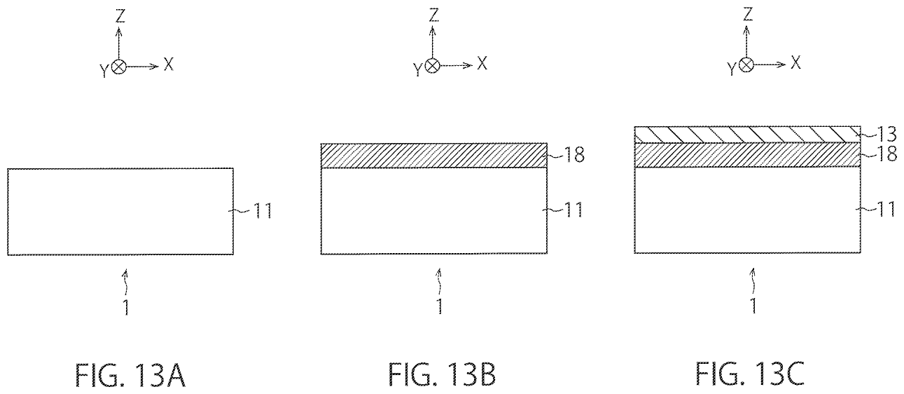

FIGS. 13A to 16C are sectional views showing a method of manufacturing a semiconductor device of a second embodiment.

The method of the present embodiment is performed using a conductor layer 18 instead of the insulator 12. The conductor layer 18 is an example of a first conductor layer. In the description of the second embodiment, the description of the common matters to the first embodiment and the second embodiment is properly omitted.

First, the substrate 11 for the wafer 1 is prepared (FIG. 13A). An example of the substrate 11 is a semiconductor substrate such as a silicon substrate.

Next, the conductor layer 18 is formed on the substrate 11 (FIG. 13B). In contrast to a semiconductor layer being a layer formed of semiconductor, the conductor layer 18 is a layer formed of conductor. An example of the conductor layer 18 is a metal layer or a graphite layer. An example of a thickness of the conductor layer 18 is 10 to 100 nm. An example of a resistivity of the conductor layer 18 is 0.05 Ω·cm or less.

Next, the porous layer 13 is formed on the conductor layer 18 (FIG. 13C). An example of the porous layer 13 is a porous semiconductor layer such as a porous polysilicon layer. For example, the porous layer 13 is formed by forming a material layer for forming the porous layer 13 on the conductor layer 18, and then, forming pores in the material layer. Namely, the porous layer 13 is formed by making the material layer porous. For example, the material layer is made porous by putting the substrate 11 in the aforementioned semiconductor manufacturing apparatus 101, and then, applying the anodization method to the material layer.

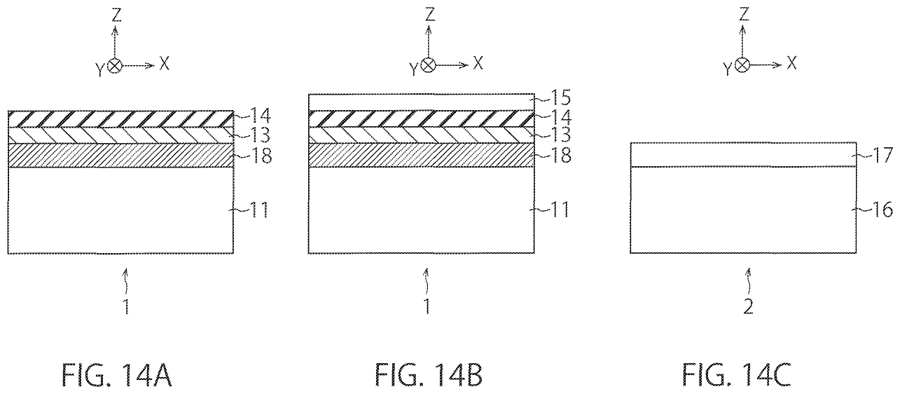

Next, the diffusion preventing layer 14 is formed on the porous layer 13 (FIG. 14A). Next, the device layer 15 is formed on the diffusion preventing layer 14 (FIG. 14B). Next, the substrate 16 for the wafer 2 is prepared, and the device layer 17 is formed on the substrate 16 (FIG. 14C).

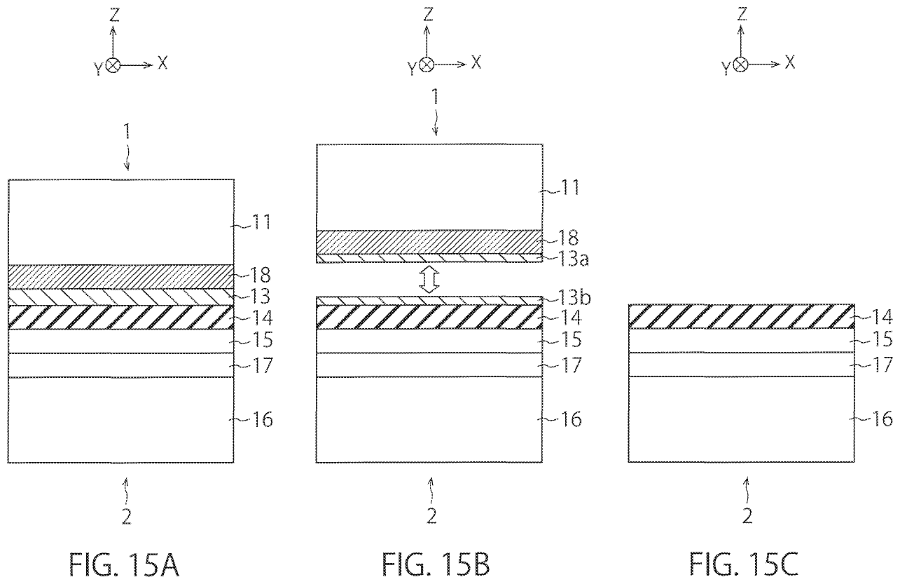

Next, the wafer 1 and the wafer 2 are bonded (FIG. 15A). Specifically, the substrate 11 and the substrate 16 are bonded so as to sandwich the conductor layer 18, the porous layer 13, the diffusion preventing layer 14, the device layer 15, and the device layer 17.

Next, the wafer 1 and the wafer 2 bonded are separated (FIG. 15B). The wafer 1 and the wafer 2 of the present embodiment are separated such that the porous layer 13 is divided into the porous layer 13a and the porous layer 13b.

In the present embodiment, the substrate 11 and the substrate 16 bonded in the step of FIG. 15A are separated in the step of FIG. 15B. In this stage, the porous layer 13 is divided into the porous layer 13a and the porous layer 13b as mentioned above. Consequently, the conductor layer 18 and the porous layer 13a remain on the substrate 11, and the device layer 17, the device layer 15, the diffusion preventing layer 14, and the porous layer 13b remain on the substrate 16.

Next, the porous layer 13b is removed from the wafer 2 (FIG. 15C). After that, the wafer 2 is divided into a plurality of chips by a dicing step.

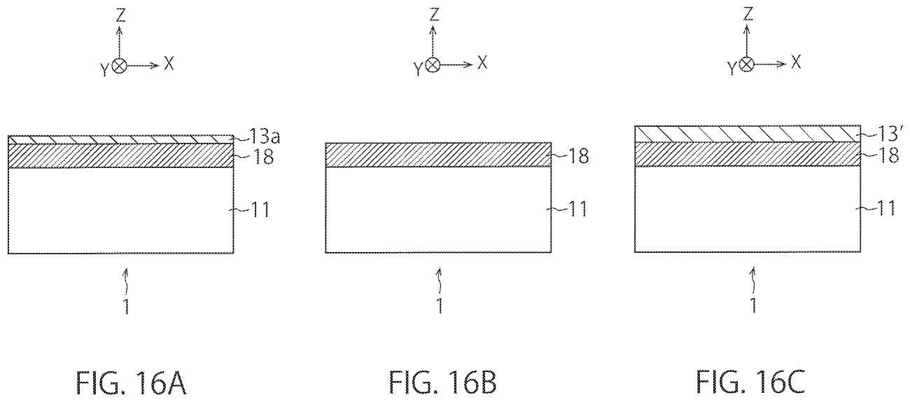

FIG. 16A shows the wafer 1 separated from the wafer 2. In this method, next, the porous layer 13a is removed from the wafer 1 (FIG. 16B). The porous layer 13a is removed, for example, by wet etching. An example of a liquid chemical used in this wet etching is a mixed aqueous solution including HF, HNO₃, and CH₃COOH. The porous layer 13a may be removed by CMP instead of the wet etching.

When the porous layer 13a is removed by the wet etching, the conductor layer 18 is used as an etching stopper against the wet etching. This makes it possible to remove the porous layer 13a such that the substrate 11 is not made thin by the wet etching. In general, when the porous layer 13a is a semiconductor layer, an etching selectivity between the porous layer 13a and the conductor layer 18 is high. Moreover, in general, when the substrate 11 is a semiconductor substrate and the porous layer 13a is a semiconductor layer, an etching selectivity between the substrate 11 and the porous layer 13a is low. Namely, the etching selectivity between the substrate 11 and the conductor layer 18 is higher than the etching selectivity between the substrate 11 and the porous layer 13a. Therefore, the present embodiment makes it possible, by using the conductor layer 18 as an etching stopper, to perform wet etching suitably. Likewise, when the porous layer 13a is removed by CMP, the conductor layer 18 is used as a polishing stopper against the CMP.

Next, the porous layer 13′ similar to the porous layer 13 is formed on the conductor layer 18 remaining on the substrate 11 (FIG. 16C). After that, the steps of FIGS. 13C to 16B are reperformed using the wafer 1 that includes the porous layer 13′. This makes it possible to reuse the substrate 11 for the wafer 1 for manufacturing a semiconductor device.

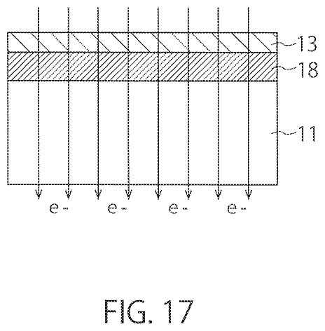

FIG. 17 is a sectional view showing details of the method of manufacturing the semiconductor device of the second embodiment.

FIG. 17 shows the substrate 11, the conductor layer 18, and the porous layer 13 during performing the anodization method. FIG. 17 further shows charges used in the anodization method. When the anodization is performed, charges move in the substrate 11, the conductor layer 18, and the aforementioned material layer. When the anodization method is performed in the first embodiment, there is a concern that the insulator 12 disturbs movement of the charges. Therefore, in the first embodiment, the thickness of the insulator 12 is desirably made thin such that the insulator 12 does not disturb the movement of the charges. On the other hand, the present embodiment makes it possible, by using the conductor layer 18 instead of the insulator 12, to restrain such disturbance of charge movement. Therefore, a resistivity of the conductor layer 18 is preferably low, for example, preferably 0.05 Ω·cm or less. A preferable example of the conductor layer 18 is a metal layer or a graphite layer.

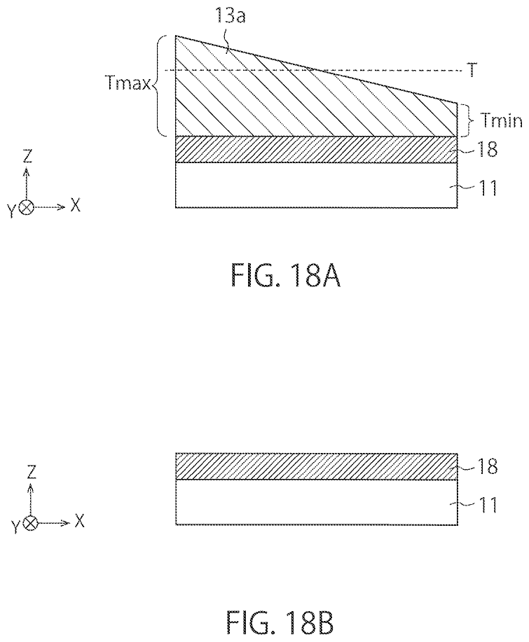

FIGS. 18A and 18B are sectional views showing details of the method of manufacturing the semiconductor device of the second embodiment.

FIGS. 18A and 18B respectively show the wafer 1 in FIGS. 16A and 16B, that is, the wafer 1 before removing and after removing the porous layer 13a. Note that FIG. 18A shows a maximum thickness “Tmax”, a minimum thickness “Tmin”, and an average thickness “T” of the porous layer 13a. While in FIG. 18A, the porous layer 13a has a shape having an inclined upper face, it may have another shape. For example, the porous layer 13a may have a shape having an upper face with roughness. In this case, for example, the thickness of the porous layer 13a at the highest point among projections of the upper face of the porous layer 13a is the maximum thickness “Tmax”, and the thickness of the porous layer 13a at the lowest point among recesses of the upper face of the porous layer 13a is the minimum thickness “Tmin”.

When the porous layer 13a is removed by wet etching, a thickness by which the porous layer 13a is etched is desirably larger than the average thickness “T” and, for example, is desirably set to be about 1.3 times of the average thickness “T”. This makes it possible to remove the porous layer 13a completely in many cases. For example, this makes it possible to restrain the porous layer 13a at the portion having the maximum thickness “Tmax” from remaining after the etching. The same also applies to the case where the porous layer 13a is removed by CMP. Since the surface of the porous layer 13a is often rough, the wet etching and the CMP are preferably performed in this manner. That the surface of the porous layer 13a is rough in the present embodiment means that the porous layer 13a has different thicknesses depending on positions thereon in the X-direction or in the Y-direction. Furthermore, the method of the present embodiment makes it possible to restrain the conductor layer 18 from being excessively removed when the porous layer 13a is removed by wet etching. This accordingly makes it possible to cause the conductor layer 18 to remain on the substrate 11 such that the substrate 11 is readily reused.

It has been employed to set the thickness by which the etching is performed to be about 1.3 times of the average thickness “T”, not being limited to this. For example, the thickness by which the etching is performed may be set in accordance with a difference between the maximum thickness “Tmax” and the minimum thickness “Tmin” of the porous layer 13a shown in FIG. 18A. In other words, the thickness by which the etching is performed may be set in accordance with a variation in thicknesses of the porous layer 13a after the bonded wafer 1 and wafer 2 are separated.

As above, in the present embodiment, the porous layer 13 is formed on the substrate 11 via the conductor layer 18, and the substrate 11 and the substrate 16 are bonded. Further, after the substrate 11 and the substrate 16 are bonded, the substrate 11 and the substrate 16 are separated. Therefore, the present embodiment makes it possible to separate these substrates 11 and 16 suitably after the bonding. For example, this makes it possible to separate the substrate 11 and the substrate 16 readily with the plane in the porous layer 13 being as the boundary and/or to remove the porous layer 13a from the substrate 11 in a mode suitable for reusing the substrate 11. Moreover, using the conductor layer 18 as a stopper in removing the porous layer 13a from the substrate 11 makes it possible to make the selectivity between the porous layer 13a and the stopper high.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a first insulator or a first conductor layer on a first substrate;
forming a porous layer on the first insulator or the first conductor layer;
forming a first film including a first device, above the porous layer;
forming a second film including a second device, on a second substrate;
bonding the first substrate and the second substrate to sandwich the first insulator or the first conductor layer, the porous layer, the first film, and the second film; and
separating the first substrate and the second substrate such that the first insulator or the first conductor layer and a first portion of the porous layer remain above the first substrate, and a second portion of the porous layer remains above the second substrate.

2. The method of claim 1, further comprising removing the first portion from the first substrate, after separating the first substrate and the second substrate.

3. The method of claim 2, wherein the first portion is removed from the first substrate by CMP (Chemical Mechanical Polishing) or wet etching.

4. The method of claim 1, wherein an etching selectivity between the first insulator or the first conductor layer and the first substrate is higher than an etching selectivity between the porous layer and the first substrate.

5. The method of claim 1, wherein the porous layer is a semiconductor layer.

6. The method of claim 5, wherein the semiconductor layer includes p-type impurity atoms or n-type impurity atoms.

7. The method of claim 6, wherein a concentration of the p-type impurity atoms or the n-type impurity atoms in the semiconductor layer is 2.5×10²⁰ atoms/cm³ or more.

8. The method of claim 1, wherein the porous layer is formed by an anodization method.

9. The method of claim 1, wherein a porosity of the porous layer is 40% or more.

10. The method of claim 1, wherein a thickness of the porous layer is 100 to 20000 nm.

11. The method of claim 1, wherein a resistivity of the porous layer is equal to or less than a two-thousandth of a resistivity of the first substrate.

12. The method of claim 1, wherein a resistivity of the first substrate is 20 to 30 Ω·cm.

13. The method of claim 1, wherein the first insulator includes silicon.

14. The method of claim 1, wherein a thickness of the first insulator is 20 nm or less.

15. The method of claim 1, wherein the first conductor layer is a metal layer or a graphite layer.

16. The method of claim 1, wherein a thickness of the first conductor layer is 10 to 100 nm.

17. The method of claim 1, wherein a resistivity of the first conductor layer is 0.05 Ω·cm or less.

18. The method of claim 1, wherein the first device includes a memory cell array, and the second device includes a circuit that controls the memory cell array.

19. A method of separating a substrate, comprising:
forming a first insulator or a first conductor layer on a first substrate;
forming a porous layer on the first insulator or the first conductor layer;
bonding the first substrate and a second substrate to sandwich the first insulator or the first conductor layer and the porous layer; and
separating the first substrate and the second substrate such that the first insulator or the first conductor layer and a first portion of the porous layer remain above the first substrate, and a second portion of the porous layer remains above the second substrate.

20. The method of claim 19, further comprising removing the first portion from the first substrate to reuse the first substrate, after separating the first substrate and the second substrate.
